(19) United States
(12) Patent Application Publication
(10) Pub. No.: US 2025/0006103 A1
(43) Pub. Date: Jan. 2, 2025

(54) DISPLAY PANEL DRIVING DEVICE AND METHOD

(71) Applicant: Magnachip Mixed-Signal, Ltd., Cheongju-si (KR)

(72) Inventors: Kwon Young OH, Cheongju-si (KR); Sang Kyung KIM, Cheongju-si (KR); Jae Joong MIN, Cheongju-si (KR)

(73) Assignee: Magnachip Mixed-Signal, Ltd., Cheongju-si (KR)

(21) Appl. No.: 18/644,926

(22) Filed: Apr. 24, 2024

(30) Foreign Application Priority Data
Jun. 30, 2023 (KR) 10-2023-0084792

(51) Int. Cl. G09G 3/20

(52) U.S. Cl. CPC G09G 3/2096; G09G 2320/0223; G09G 2320/043; G09G 2330/021; G09G 2370/00

(57) ABSTRACT

A display panel driving device includes a control IC, a power management integrated circuit (PMIC), and a digital circuit unit configured to drive a display panel. The digital circuit unit is supplied with an adjusted external power supply voltage according to a load mode of the digital circuit unit to control driving of the display panel, and the control IC is configured to control the PMIC according to the load mode and enable the external power supply voltage to be variably supplied to the digital circuit unit according to the control operation of the control IC.

### CROSS-REFERENCE TO RELATED APPLICATION

This application claims the benefit under 35 U.S.C. § 119 (a) of Korean Patent Application No. 10-2023-0084792 filed on Jun. 30, 2023, in the Korean Intellectual Property Office, the entire disclosure of which is incorporated herein by reference for all purposes.

### BACKGROUND

### 1. Field

The following description relates to a display panel driving device and method, and more particularly to a display panel driving device and method for driving a display panel while applying an external power supply voltage variably according to a load mode of a digital circuit unit included in a display driver IC (DDIC) that drives the display panel.

### 2. Description of Related Art

In a display device, such as a liquid crystal display (LCD), a display driver integrated circuit (DDIC) is a semiconductor chip that drives a display panel. The DDIC is supplied with its driving power based on the load conditions for driving the display panel. Conventionally, DDICs have generated an internal power supply voltage from the power supplied by a power management integrated circuit (PMIC) and transmitted a signal to a display panel for control.

However, as the resolution of the display panel gradually increased, it became difficult to drive the panel using only the internal power supply voltage of the display device, and an external power supply voltage (external VDD) became necessary.

The PMIC applies an external power supply voltage to the DDIC via a connector or the like. In this case, IR voltage drop occurs due to the resistive components of the display device's PCB board, connectors, vias, etc. The IR voltage drop increases as the load current of the DDIC increases. Therefore, to compensate for the voltage drop, the external power supply voltage must also be supplied at a lower level.

However, if the external power supply voltage is not adjusted, the problem of reduced DDIC lifetime occurs. For example, after the display device is changed from heavy mode to light mode, the external power supply voltage remains at a high level, exceeding the maximum operating voltage (VDD max), which is important to ensure the lifetime of the DDIC. As is well known, semiconductor chips such as DDICs have a shortened lifespan when supplied with a power supply voltage that exceeds their maximum operating voltage. In this case, an increase in external power supply voltage will inevitably lead to an increase in leakage current.

Conversely, when changing from light mode to heavy mode, the increased current consumption leads to a decrease in the external power supply voltage. As a result, the external power supply voltage may fall below the minimum operating voltage (VDD min) required to ensure operation of the DDIC. The DDIC will then not be able to operate normally.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a display panel driving device includes a control integrated circuit (IC) and a power management integrated circuit (PMIC), and a digital circuit unit configured to drive a display panel. The digital circuit unit is supplied with an adjusted external power supply voltage according to a load mode of the digital circuit unit to control driving of the display panel, and the control IC is configured to control the PMIC according to the load mode and enable the external power supply voltage to be variably supplied to the digital circuit unit according to the control operation of the control IC.

The load mode may include a light mode and a heavy mode. An amount of IR voltage drop may vary depending on the load mode, and the adjusted external power supply voltage by the amount of IR voltage drop may be supplied.

In the heavy mode where a load current is highest, the digital circuit unit may be supplied with the adjusted external power supply voltage to be greater than or equal to a minimum operating voltage (VDD min) that ensures operation of the digital circuit unit.

In the light mode having a lower load current than the heavy mode, the digital circuit unit may be supplied with the adjusted external power supply voltage do not exceed a maximum operating voltage (VDD max) that ensures lifetime of the digital circuit unit.

The external power supply voltage may be adjusted by an amount of IR voltage drop to be supplied to the digital circuit unit.

The control IC and the PMIC may be mounted on a printed circuit board (PCB). The PCB and the digital circuit unit may be connected by a packaging type. The packaging type may be one of chip on film (COF), chip on glass (COG), or chip on plastic (COP).

The display panel driving device may further include an interface unit configured to connect the control IC and the digital circuit unit, and the interface unit may be configured to support a digital communication method and an analog communication method.

The digital circuit unit may be configured to transmit load mode information to the control IC upon request from the control IC, and the control IC may be configured to control the PMIC according to the load mode and enable the external power supply voltage to be variably supplied to the digital circuit unit.

In another general aspect, a display panel driving device includes a digital circuit unit and a power management integrated circuit (PMIC). The PMIC is configured to supply an external power supply voltage to the digital circuit unit according to a load mode of the digital circuit unit.

The display panel driving device may further include a control IC. The digital circuit unit may be configured to transmit load mode information to the PMIC upon request from the control IC, and the PMIC may be configured to control the external power supply voltage to be variably supplied to the digital circuit unit depending on the load mode.

The load mode may include a light mode and a heavy mode, and an amount of IR voltage drop varies depending on the load mode of the digital circuit unit, and the external power supply voltage adjusted by the amount of the IR voltage drop is supplied to the digital circuit unit.

In a first mode having a high load of the digital circuit unit, the external power supply voltage may be adjusted to be greater than or equal to a minimum operating voltage (VDD min) that ensures operation of the digital circuit unit, and in a second mode having a lower load of the digital circuit unit than the first mode, the external power supply voltage may be adjusted to not exceed a maximum operating voltage (VDD max) that ensures lifetime of the digital circuit unit.

In another general aspect, a method of driving a display panel in a display panel driving device configured to control driving of the display panel, the method includes transmitting and receiving, by a control IC, load mode information of a digital circuit unit; and adjusting, by a power management integrated circuit (PMIC), an external power supply voltage according to a load mode of the digital circuit unit to supply the adjusted external power supply voltage to the digital circuit unit.

When a load current of the digital circuit unit increases, the external power supply voltage may be adjusted to be greater than or equal to a minimum operating voltage (VDD min) that ensures operation of the digital circuit unit.

When a load current of the digital circuit unit decreases, the external power supply voltage may be adjusted to not exceed a maximum operating voltage (VDD max) that ensures lifetime of the digital circuit unit.

In another general aspect, a method of driving a display panel in a display panel driving device configured to control driving of the display panel includes transmitting and receiving, by a power management integrated circuit (PMIC), load mode information of a digital circuit unit; and adjusting, by the PMIC, an external power supply voltage according to a load mode of the digital circuit unit to supply the adjusted external power supply voltage to the digital circuit unit.

When a load current of the digital circuit unit increases, the external power supply voltage may be adjusted to be greater than or equal to a minimum operating voltage (VDD min) that ensures operation of the digital circuit unit.

When a load current of the digital circuit unit decreases, the external power supply voltage may be adjusted to not exceed a maximum operating voltage (VDD max) that ensures lifetime of the digital circuit unit.

### BRIEF DESCRIPTION OF THE DRAWINGS

FIG. 1 illustrates an overall block diagram showing a display panel driving device according to a first embodiment of the present disclosure.

FIG. 2 illustrates an example flow diagram in which a control IC checks a load mode of a digital circuit unit to supply an external power supply voltage according to a first embodiment of the present disclosure.

FIG. 3 illustrates an example flow diagram in which a PMIC checks a load mode of a digital circuit unit to supply an external power supply voltage according to a first embodiment of the present disclosure.

FIG. 4 illustrates an overall block diagram of a display panel driving device according to a second embodiment of the present disclosure.

FIG. 5 illustrates a graph illustrating the operating conditions when the external power supply voltage is not regulated, even if the load current of the digital circuit unit changes.

FIG. 6 illustrates a graph showing the operating conditions when an external power supply voltage is regulated as the load current of the digital circuit unit changes.

Other features and aspects will be apparent from the following detailed description, the drawings, and the claims.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section.

The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terms indicating a part such as “part” or portion” used herein to mean that the component may represent a device that may include a specific function, a software that may include a specific function, or a combination of device and software that may include a specific function, but it is not necessarily limited to the function expressed. This is only provided to help a more general understanding of one or more examples herein, Various modifications and variations are possible from these descriptions by those of ordinary skill in the art to which the one or more examples pertains.

The features of the examples described herein may be combined in various ways as will be apparent after an understanding of the disclosure of this application. Further, although the examples described herein have a variety of configurations, other configurations are possible as will be apparent after an understanding of the disclosure of this application.

A detailed description is given below, with attached drawings. The features of the examples described herein may be combined in various ways as will be apparent after an understanding of the disclosure of this application. Further, although the examples described herein have a variety of configurations, other configurations are possible as will be apparent after an understanding of the disclosure of this application.

Accordingly, the spirit of the present disclosure should not be limited to the described embodiments, and it will be said that not only the claims to be described later, but also all those that have equivalent or equivalent modifications to the claims belong to the scope of this disclosure.

The present disclosure relates to a display panel driving device and method that enables a Power Management Integrated Circuit (PMIC) to adaptively supply a power voltage according to a load mode of a digital circuit unit included in a Display Driver IC (DDIC).

The present disclosure provides a display panel driving device and method for preventing life deterioration of a semiconductor chip supplying a power voltage to a display panel even when a mode change occurs based on a load mode of a digital circuit unit included in a Display Driver IC (DDIC).

The technical challenges of the present disclosure are not limited to the technical challenges mentioned above, and other technical challenges not mentioned will be apparent to those skilled in the art from the following description.

Hereinafter, the present disclosure will be described in more detail on the basis of the embodiments shown in the drawings.

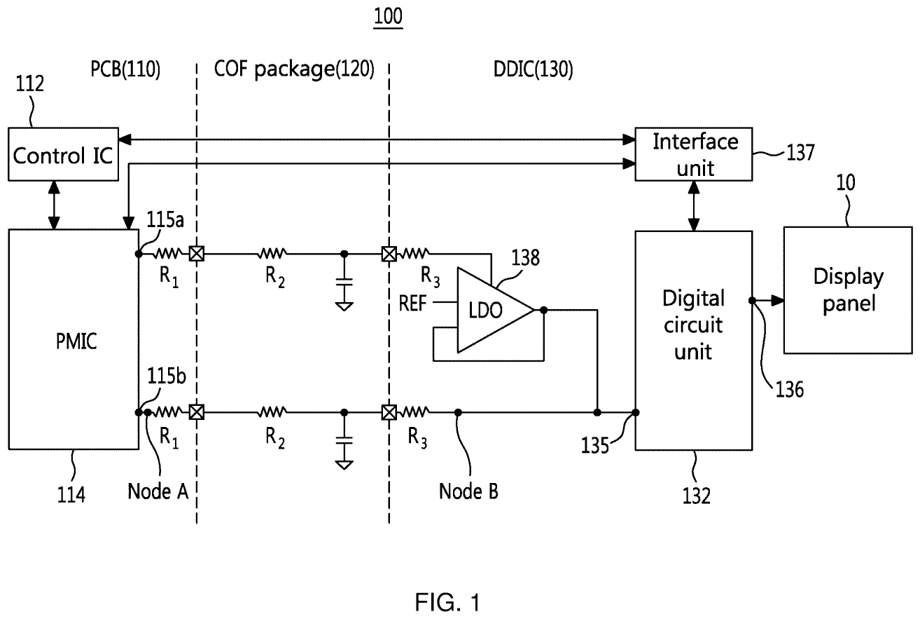

FIG. 1 illustrates an overall block diagram of a display panel driving device according to a first embodiment of the present disclosure.

A display panel driving device 100 according to the present disclosure may be a device designed with circuit modules in various packaging methods. The packaging methods may include Flexible Printed Circuit (FPC), Tape Carrier Package (TCP), Chip On Glass (COG), Chip On Flexible Printed Circuit or Chip On Film (COF), Chip On Plastic (COP), etc. These packaging methods aim to align with the trend in semiconductor packaging, emphasizing lighter, thinner, shorter, and smaller designs. They involve technologies such as mounting chips on flexible polyimide film or thin plastic.

In examples of the present disclosure, a device designed by a Chip On Film (COF) packaging method is illustrated. The COF technology may be a packaging method for responding to the trend of light, thin, short, and small communication devices in a display driver Integrated Circuit (display driver IC).

Referring to FIG. 1, the display panel driving device 100 in the present disclosure may include a Printed Circuit Board (PCB) 110, a COF package 120, a display driver IC (DDIC) 130, and others. Through these components, a display panel 10 is driven. Herein, it is noted that use of the term ‘may’ with respect to an example or embodiment, e.g., as to what an example or embodiment may include or implement, means that at least one example or embodiment exists where such a feature is included or implemented while all examples and embodiments are not limited thereto.

According to examples of the present disclosure, the PCB 110 includes a control IC 112, a Power Management Integrated Circuit (PMIC) 114, and others.

The control IC 112 may control various driving devices including a Central Processing Unit (CPU) chip, a Graphics Processing Unit (GPU) chip, and an Application Processor (AP) chip. The control IC 112 serves to control the PMIC 114 based on the load conditions of a digital circuit unit 132 driving the display panel 10. This is possible because the control IC 112 transmits the resolution information, scan rate information, operating state such as standby state or driving state, pattern information, etc. of the display panel 10 to the digital circuit unit 132 to control them.

The PMIC 114 supplies a driving power necessary to drive the digital circuit unit 132. The driving power supplied by the PMIC 114 may include an internal power supply voltage of the display panel driving device 100 and a separate external power supply voltage. Specifically, the PMIC 114 includes a first supply terminal 115a and a second supply terminal 115b. The first supply terminal 115a may be a terminal for supplying an internal power supply voltage as driving power, and the second supply terminal 115b may be a terminal for supplying an external power supply voltage as driving power. The external power supply voltage is intended for cases where the digital circuit unit 132 cannot be driven normally by the internal power supply voltage alone, i.e., as the resolution of the display panel 10 increases, the load current of the digital circuit unit 132 increases, requiring more driving power to be applied.

Here, the PMIC 114 is connected to the DDIC 130 by a board connector to supply an external power supply voltage. Thus, when the PMIC 114 supplies an external power supply voltage, an IR voltage drop may occur due to various resistance components such as connectors that connect the PMIC 114 and the DDIC 130, vias, pads, etc.

The PMIC 114 may variably adjust an external power supply voltage through the second supply terminal 115b. The external power supply voltage is adjusted to increase or decrease to supply the digital circuit unit 132 depending on a load described below (see Table 1).

According to one or more examples of the present disclosure, the COF package 120 connects the PCB 110 and the DDIC 130. The COF package 120 is a method of packaging a chip by mounting it on a polyimide film, aligning with the high quality and high-performance requirements of a display device. Of course, in addition to these COF packaging, the present disclosure enables the display panel driving device to be configured by packaging methods such as COG packaging techniques, COP packaging techniques, and other packaging techniques.

According to one or more examples of the present disclosure, the DDIC 130 is supplied with driving power for a display panel from the PMIC 114 to control the operation of the display panel 10. This DDIC 130 may be configured to include the digital circuit unit 132, an interface unit 137, and others.

The digital circuit unit 132 may be formed of various logic elements and includes an input terminal 135 and an output terminal 136. The input terminal 135 is for receiving driving power from the PMIC, and the output terminal 136 is for applying driving power to the display panel 10.

The digital circuit unit 132 may operate according to a load mode, as indicated in Table 1. This is to allow the PMIC 114 to flexibly control the power supply voltage according to the load conditions of the digital circuit unit 132. Here, the distinction between light mode and heavy mode is merely one example, and may be further differentiated by including other operating modes, such as standby mode and normal mode.

TABLE 1

| Operation mode | Consumption Current of the Digital Circuit Unit |
|---|---|
| Light mode | Lower current consumption compared to Heavy mode |
| Heavy mode | Higher current consumption compared to Light mode |

In Table 1, operation modes may be categorized according to factors such as, for example, frequency or load current.

The present disclosure includes increasing or decreasing a driving power supplied to the digital circuit unit 132 based on a mode of operation by the PMIC 114. Thus, when a mode change from a light mode to a heavy mode occurs, it is necessary to increase the driving power supplied to the digital circuit unit 132.

According to one or more examples of the present disclosure, the DDIC 130 includes an LDO regulator 138. As is known, an LDO regulator is a component designed to continuously maintain the level of an output voltage at a target level. The LDO regulator 138 is connected to the first supply terminal 115a. The LDO regulator 138 may be in a normally turn-on (operational) state or in a turn-off (non-operational) state.

In examples of the present disclosure, the interface unit 137 is configured for the control IC 112 to transmit various data required to drive the display panel 10 to the digital circuit unit 132. Additionally, as needed, the control IC 112 may check the load status of the digital circuit unit 132 via the interface unit 137. The interface unit 137 supports digital interface methods such as S-wire, Inter-Integrated Circuit (I2C), Improved Inter-Integrated Circuit (I3C), and the like, as well as analog methods that can transmit analog signals such as voltage.

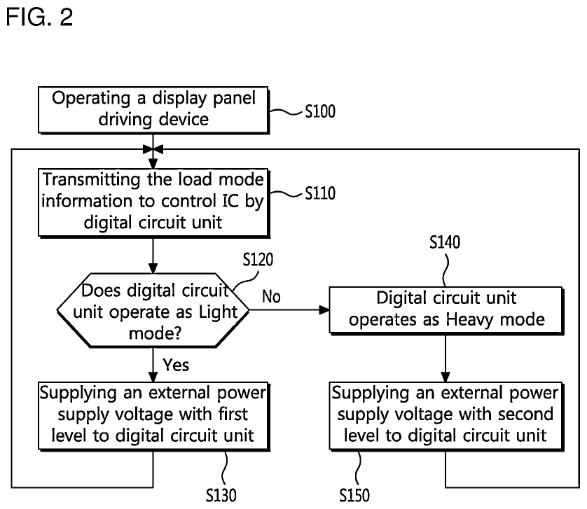

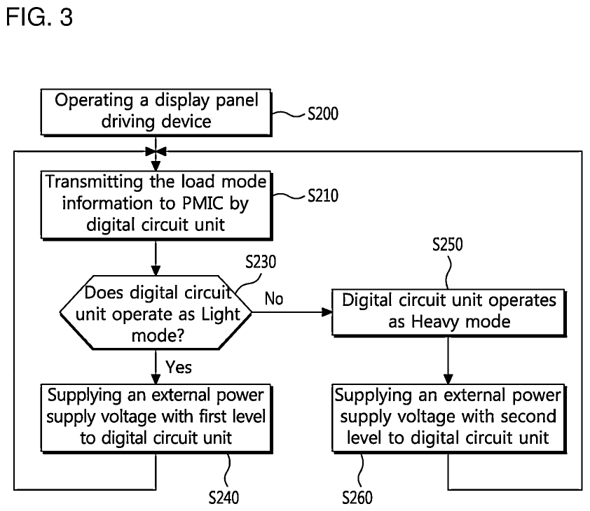

In the following, an exemplary operation of a display panel driving device is described with reference to FIGS. 2 and 3.

In FIGS. 2 and 3, a description of a mode in which a PMIC 114 drives a display panel 10 by supplying an internal power supply voltage through a first supply terminal 115a will be omitted. This is because the present disclosure is configured to drive the display panel with an external power supply voltage under the assumption that the display panel cannot normally be driven with an internal power supply voltage alone.

FIG. 2 illustrates an exemplary flow diagram in which a control IC determines the load mode of a digital circuit unit to supply an external power supply voltage, according to one embodiment of the present disclosure.

When the display panel driving device 100 operates (S100), the digital circuit unit 132 transmits load mode information to the control IC 112 through the interface unit 137 (S110). Alternatively, when the control IC 112 transmits a signal to the digital circuit unit 132 through the interface unit 137 to check the load mode information, the digital circuit unit 132 may transmit the load mode information to the control IC 112 through the interface unit 137. The operation of checking the load mode of the digital circuit unit 132 may be verified because the control IC 112 directly controls the digital circuit unit 132 that drives the display panel 10. The load mode information may include resolution information, refresh rate information, operation state of the display panel 10 in a standby state or a driving state, pattern information, and the like.

Based on real-time verification results of the load mode, the control IC 112 may control the supply of the external power supply voltage differently. The load mode may include a light mode and a heavy mode, as referenced in Table 1.

Specifically, this is when the digital circuit unit 132 is in the light mode (S120). For example, this may be the case when the mode is changed from heavy mode to light mode.

In that case, the control IC 112 controls the PMIC 114 to adjust the external power supply voltage to a first level to be supplied to the digital circuit unit 132 through the second supply terminal 115b (S130). The first level may be a value set not to exceed a maximum operating voltage (VDD max) to ensure longevity of the digital circuit unit 132. This is because the change from heavy mode to light mode may reduce the load current, and a reduced load current results in a reduced IR voltage drop. In this case, if the driving power supplied in the heavy mode is applied to the digital circuit unit 132, the digital circuit unit 132 may be damaged, so the driving power must be supplied within the maximum operating voltage (VDD max).

Conversely, this is when the digital circuit unit 132 is in heavy mode (S140). For example, this may be the case when the mode is changed from light mode to heavy mode.

In this case, the control IC 112 controls the PMIC 114 to adjust the external power supply voltage to a second level and supply it to the digital circuit unit 132 (S150) via the second supply terminal 115b. The second level may be a value set to ensure a minimum operating voltage (VDD min) at which the digital circuit unit 132 can operate reliably. This is because changing from a light mode to a heavy mode may cause the IR voltage to drop significantly because more load current is being used. In this case, the operation of the digital circuit unit 132 may stop if the external power supply voltage supplied to the digital circuit unit 132 falls below a minimum operating voltage (VDD min) due to the IR voltage drop.

In this way, the control IC 112 controls the PMIC 114 to increase or decrease the external power supply voltage supplied to the digital circuit unit 132 in response to the load conditions of the digital circuit unit 132, so that the display panel 10 can be operated normally even when the load mode is changed.

FIG. 3 illustrates an exemplary flow diagram in which a PMIC checks the load mode of a digital circuit unit to supply an external power supply voltage, according to one embodiment of the present disclosure.

The overall flow diagram is similar to FIG. 2, but the PMIC 114 receives load mode information via the interface unit 137 to control the load mode of the digital circuit unit 132.

When the display panel driving device 100 is driven (S200), the digital circuit unit 132 may transmit the load mode information to the PMIC 114 via the interface unit 137 (S210). Alternatively, when the control IC 112 transmits a signal to the digital circuit unit 132 via the interface unit 137 to check the load mode information, the digital circuit unit 132 may transmit the load mode information to the PMIC 114 via the interface unit 137. The load mode information may include resolution information of the display panel 10, refresh rate information, operation state of the standby state or driving state, pattern information, and the like. When the PMIC 114 checks and controls the load mode information, the load of the digital circuit unit 132 may be reduced.

The PMIC 114 controls the external power supply voltage to be supplied differently depending on the load mode of the digital circuit unit 132. The load mode may be light mode and heavy mode, as referenced in Table 1.

Specifically, this is when the digital circuit unit 132 changes from heavy mode to light mode (S230).

In this case, the PMIC 114 adjusts the external power supply voltage to a first level and supplies it to the digital circuit unit 132 via the second supply terminal 115b (S240). The first level may be a value set not to exceed a maximum operating voltage (VDD max) to ensure longevity of the digital circuit unit 132. This is because changing from heavy mode to light mode may results in a decrease in load current, and a decrease in load current results in a decrease in IR voltage drop. In this case, if the driving power supplied in heavy mode is applied to the digital circuit unit 132, the digital circuit unit 132 may be damaged. So the driving power must be supplied within the maximum operating voltage (VDD max).

Conversely, in S250, the digital circuit unit 132 is in the heavy mode. For example, the mode is changed from light mode to heavy mode.

In this case, the PMIC 114 adjusts the external power supply voltage to a second level via the second supply terminal 115b and supplies it to the digital circuit unit 132 (S260). The second level may be a value set to ensure a minimum operating voltage (VDD min) at which the digital circuit unit 132 can operate reliably. This is because when the mode is changed from light mode to heavy mode, more load current is used, which can cause the IR voltage to drop significantly. In this case, if the voltage drops below the minimum operating voltage (VDD min), the operation of the digital circuit unit 132 may stop.

In FIG. 3, the PMIC 114 checks the load mode of the digital circuit unit 132 and controls the external power supply voltage to increase or decrease so that the display panel 10 can operate normally.

According to the present disclosure, the external power supply voltage is adjusted variably according to the load mode of the digital circuit unit 132 and supplied, so that the display panel 10 may be operated under optimal conditions. In this way, the problem of shortened lifetime or interrupted operation of the digital circuit unit 132 when switching between light mode and heavy mode is solved.

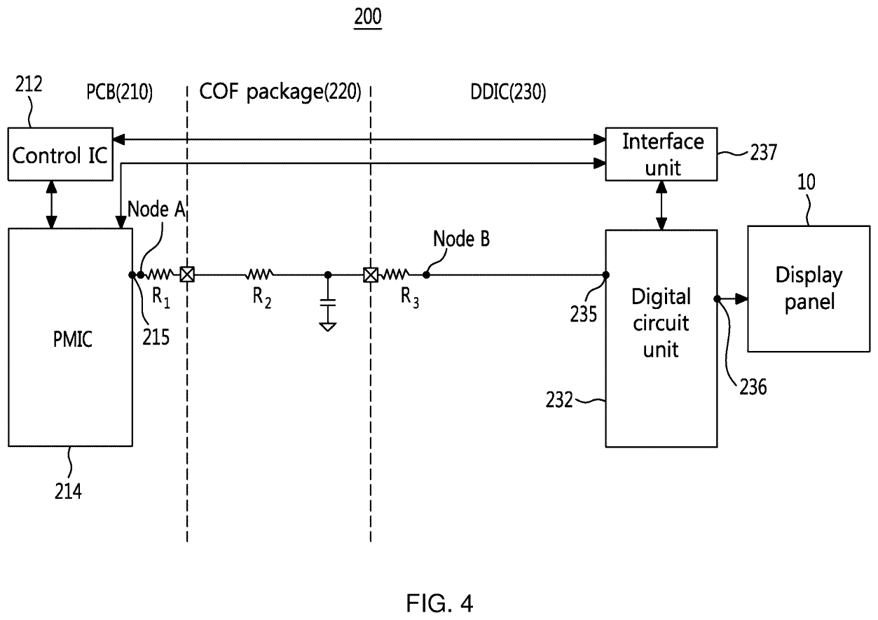

FIG. 4 illustrates an overall block diagram of a display panel driving device according to a second embodiment of the present disclosure.

Compared to the first embodiment, the second embodiment is a configuration in which only the LDO regulator element is removed. Unlike the first embodiment, removing the LDO regulator may reduce the layout area and improve power efficiency. The second embodiment also has the same configuration in which the PMIC supplies an external power supply voltage to the digital circuit unit 232. Therefore, the description of the same configuration may be omitted or simplified.

As shown in FIG. 4, a Printed Circuit Board (PCB) 210, COF package 220, Display Driver IC (DDIC) 230, and others may be included. These components drive the display panel 10.

PCB 210 includes a control IC 212 that controls power supply based on the load mode (as shown in Table 1) of the digital circuit unit 232, a power management integrated circuit (PMIC) 214 that supplies power based on the control operation of the control IC 212, and the like.

The PMIC 214 provides the driving power required to drive the digital circuit unit 232. The PMIC 214 includes a supply terminal 215 that supplies an external power supply voltage. The difference from the first embodiment is that there is no terminal to supply an internal power supply voltage.

The COF package 220 connects the PCB 210 and the DDIC 230. The display panel driving device 200 may also be configured with other packaging methods other than the COF package 220.

The DDIC 230 receives driving power for the display panel from the PMIC 214 and controls driving of the display panel 10. The DDIC 230 is configured to include the digital circuit unit 232, an interface unit 237, and the like.

The digital circuit unit 232 is composed of various logic elements and includes an input terminal 235 and an output terminal 236. The input terminal 235 is a terminal for receiving driving power, and the output terminal 236 is a terminal for applying driving power to the display panel 10.

The interface unit 237 is for the control IC 212 to transmit various data for driving the display panel 10 to the digital circuit unit 232. In addition, the control IC 212 may also check the load mode of the digital circuit unit 232 via the interface unit 237 as needed. As shown in FIG. 1, the interface unit 237 supports both digital interface methods such as S-wire, Inter-Integrated Circuit (I2C), Improved Inter-Integrated Circuit (I3C), as well as analog methods that can transmit analog signals such as voltage.

Referring to FIG. 4, there are resistance components between the PMIC 214 and the digital circuit unit 232. This is due to the fact that PMIC 214 and digital circuit unit 232 are connected by board connectors, which have various components such as connectors, vias, and pads. These resistive components cause an IR voltage drop. Therefore, there is a voltage difference between the front end (Node A) and the rear end (Node B) of the resistive components, and this voltage difference may vary depending on the load conditions of the digital circuit unit 232.

The display panel driving device 200 according to the second embodiment is performed similarly to the operation of the flow charts shown in FIGS. 2 and 3. However, it differs in that it uses only an external power supply voltage to drive the display panel, i.e., the external power supply voltage may be increased or decreased to drive the display panel 10 depending on the load mode of the digital circuit unit 232.

When the display panel driving device 200 is driven, the control IC 212 may know the load mode of the digital circuit unit 232. Then, the control IC 212 controls the PMIC 214 to differently supply the external power supply voltage to the digital circuit unit 232 based on the load mode.

Also, when the display panel driving device 200 is driven, the PMIC 214 may know the load mode of the digital circuit unit 232. Then, the PMIC 214 supplies the external power supply voltage to the digital circuit unit 232 according to the load mode.

Depending on the load mode, when the heavy mode is changed to a light mode, the external power supply voltage should be lowered because the current consumption required to drive the display panel 10 is reduced. This is because the digital circuit unit 232 may be damaged if the same external power supply voltage used in the heavy mode is applied.

Conversely, when the light mode is changed to a heavy mode depending on the load mode, the external power supply voltage should be increased because the current consumption required to drive the display panel 10 increases. If the external power supply voltage used in the light mode is applied to the digital circuit unit 232, the external power supply voltage is lowered due to the IR voltage drop. If the external power supply voltage is lower than the minimum operating voltage (VDD min) set to guarantee the operation of the digital circuit unit 232, the operation of the digital circuit unit 232 may stop.

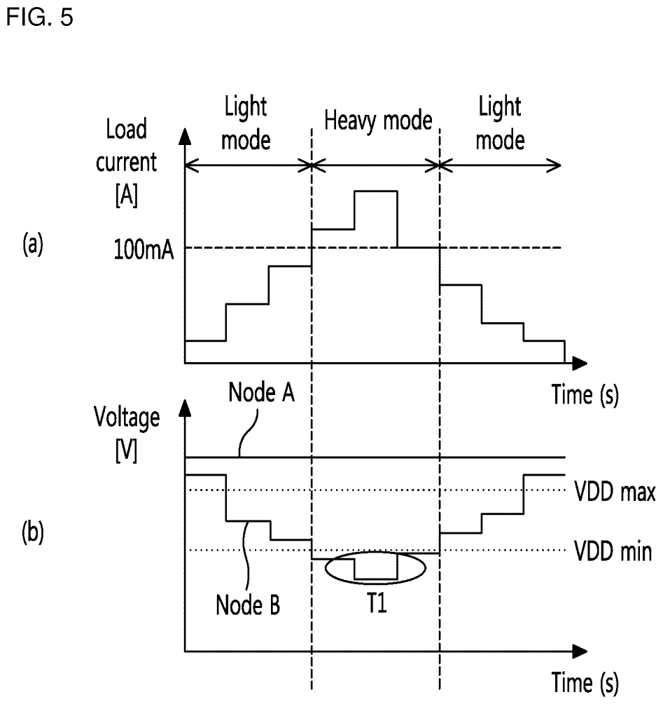

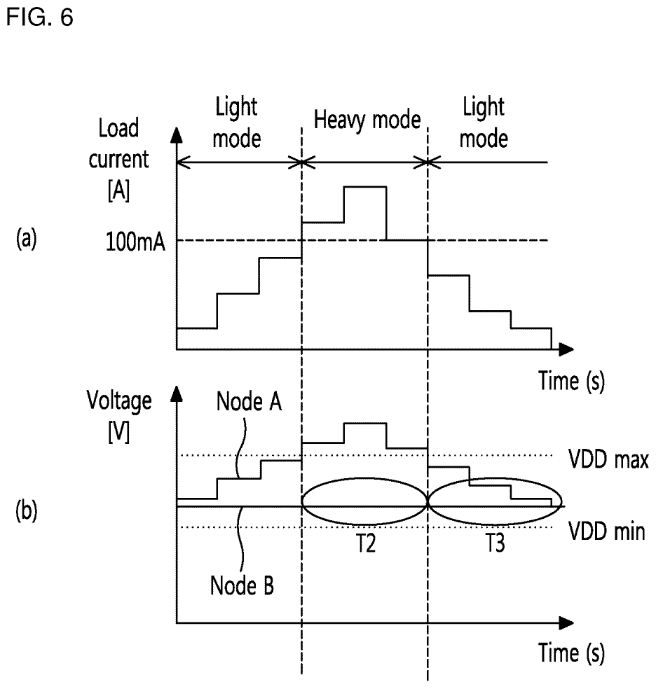

Referring to FIGS. 5 and 6, the reason why the external power supply voltage must be adjusted and supplied according to the load mode of the digital circuit unit described above will be discussed again.

FIG. 5 of (b) and FIG. 6 of (b) illustrate graphs showing the voltages of Node A and Node B shown in FIGS. 1 and 4.

FIG. 5 illustrates a graph when the external power supply voltage remains unadjusted (i.e., the voltage of Node A in FIG. 5 of (b)), as the load current of the digital circuit unit changes. FIG. 6 illustrates a graph showing the operation conditions when the external power supply voltage is adjusted according to the load mode as the load current of a digital circuit unit changes (i.e., the voltage of Node A in FIG. 6 of (b)).

In FIGS. 5 and 6, the digital circuit unit is described as operating in a light mode when the load current is in the range of 30 to 100 mA, and operating in a heavy mode when the load current is greater than or equal to 100 mA.

First, the operation of the heavy mode section is described.

When the external power supply voltage (external VDD) is not adjusted during the heavy mode section, the driving power input to the digital circuit unit during the heavy mode section may be less than or equal to the minimum operating voltage (VDD min) due to the IR voltage drop (T1 section in (b) of FIG. 5). The digital circuit unit may then fail to operate.

On the contrary, if the external power supply voltage (external VDD) is adjusted high according to the load current of the digital circuit unit, as in the heavy mode section of (b) of FIG. 6, even if the external power supply voltage is lowered due to the IR voltage drop, the driving power input to the digital circuit unit is greater than or equal to the minimum operating voltage (VDD min) to ensure the minimum operating voltage (T2 section in (b) of FIG. 6). Therefore, the digital circuit unit may continue to operate normally.

Next, the operation of the light mode section is described.

When the external power supply voltage (external VDD) is not adjusted in the light mode section, the driving power input to the digital circuit unit may exceed the maximum operating voltage (VDD max) as shown in the light mode section in (b) of FIG. 5, because the external power supply voltage supplied in the heavy mode is applied to the digital circuit unit. In other words, because the IR voltage drop is small in the light mode, the external power supply voltage may be applied to the digital circuit unit almost as is without reduction. Therefore, the life of the digital circuit unit is shortened.

On the other hand, when the external power supply voltage (external VDD) is adjusted to be low according to the load current of the digital circuit unit, the driving power input to the digital circuit unit does not exceed the maximum operating voltage (VDD max) as shown in the light mode operation (T3 section in (b) of FIG. 6). Therefore, the life of the digital circuit unit may be guaranteed.

As described above, it can be seen that the external power supply voltage may be adjusted according to the load condition of the digital circuit unit, thereby solving the problem that the life of the digital circuit unit driving and controlling the display panel decreases or the operation of the digital circuit unit stops.

According to the present disclosure, a separate external power supply voltage as well as an internal power supply voltage may be used depending on the load condition of the digital circuit unit included in the display driver IC driving the display panel, which has the effect of enabling the digital circuit unit to be driven normally even when a high load current is required due to the high resolution of the display panel.

According to the present disclosure, the external power supply voltage may be appropriately adjusted according to the load mode of the digital circuit unit included in the display driver IC, so that the digital circuit unit may optimally drive the display panel regardless of the magnitude of the load current.

According to the present disclosure, even if the load current increases or decreases depending on the load mode of the digital circuit unit included in the display driver IC, the external power supply voltage is adjusted so that it is greater than or equal to a minimum operating voltage (VDD min) that ensures the operation of the display driver IC, or the external power supply voltage is adjusted so that it does not exceed a maximum operating voltage (VDD max) that ensures the life of the display driver IC, and the operation of the display driver IC can be prevented from being interrupted.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A display panel driving device, comprising:
a control integrated circuit (IC) and a power management integrated circuit (PMIC); and
a digital circuit unit configured to drive a display panel,
wherein the digital circuit unit is supplied with an adjusted external power supply voltage according to a load mode of the digital circuit unit to control driving of the display panel, and
wherein the control IC is configured to control the PMIC according to the load mode and enable the external power supply voltage to be variably supplied to the digital circuit unit according to the control operation of the control IC.

2. The display panel driving device of claim 1, wherein the load mode comprises a light mode and a heavy mode, and
wherein an amount of IR voltage drop varies depending on the load mode, and the adjusted external power supply voltage by the amount of IR voltage drop is supplied.

3. The display panel driving device of claim 2, wherein, in the heavy mode, the digital circuit unit is supplied with the adjusted external power supply voltage to be greater than or equal to a minimum operating voltage (VDD min) that ensures operation of the digital circuit unit, and
wherein the heavy mode is a mode where a load current is highest.

4. The display panel driving device of claim 2, wherein, in the light mode, the digital circuit unit is supplied with the adjusted external power supply voltage do not exceed a maximum operating voltage (VDD max) that ensures lifetime of the digital circuit unit, and
wherein the light mode has a lower load current than the heavy mode.

5. The display panel driving device of claim 1, wherein the external power supply voltage is adjusted by an amount of IR voltage drop to be supplied to the digital circuit unit.

6. The display panel driving device of claim 1, wherein the control IC and the PMIC are mounted on a printed circuit board (PCB).

7. The display panel driving device of claim 6, wherein the PCB and the digital circuit unit are connected by a packaging type.

8. The display panel driving device of claim 7, wherein the packaging type is one of chip on film (COF), chip on glass (COG), or chip on plastic (COP).

9. The display panel driving device of claim 1, further comprising:
an interface unit configured to connect the control IC and the digital circuit unit,
wherein the interface unit is configured to support a digital communication method and an analog communication method.

10. The display panel driving device of claim 1, wherein the digital circuit unit is configured to transmit load mode information to the control IC upon request from the control IC, and
wherein the control IC is configured to control the PMIC according to the load mode and enable the external power supply voltage to be variably supplied to the digital circuit unit.

11. A display panel driving device, comprising:
a digital circuit unit; and
a power management integrated circuit (PMIC),
wherein the PMIC is configured to supply an external power supply voltage to the digital circuit unit according to a load mode of the digital circuit unit.

12. The display panel driving device of claim 11, further comprising:
a control IC,
wherein the digital circuit unit is configured to transmit load mode information to the PMIC upon request from the control IC, and
wherein the PMIC is configured to control the external power supply voltage to be variably supplied to the digital circuit unit depending on the load mode.

13. The display panel driving device of claim 11, wherein the load mode comprises a light mode and a heavy mode, and
wherein an amount of IR voltage drop varies depending on the load mode of the digital circuit unit, and the external power supply voltage adjusted by the amount of the IR voltage drop is supplied to the digital circuit unit.

14. The display panel driving device of claim 11, wherein, in a first mode having a high load of the digital circuit unit, the external power supply voltage is adjusted to be greater than or equal to a minimum operating voltage (VDD min) that ensures operation of the digital circuit unit, and
wherein, in a second mode having a lower load of the digital circuit unit than the first mode, the external power supply voltage is adjusted to not exceed a maximum operating voltage (VDD max) that ensures lifetime of the digital circuit unit.

15. A method of driving a display panel in a display panel driving device configured to control driving of the display panel, the method comprising:
transmitting and receiving, by a control IC, load mode information of a digital circuit unit; and
adjusting, by a power management integrated circuit (PMIC), an external power supply voltage according to a load mode of the digital circuit unit to supply the adjusted external power supply voltage to the digital circuit unit.

16. The method of claim 15, wherein, when a load current of the digital circuit unit increases, the external power supply voltage is adjusted to be greater than or equal to a minimum operating voltage (VDD min) that ensures operation of the digital circuit unit.

17. The method of claim 15, wherein, when a load current of the digital circuit unit decreases, the external power supply voltage is adjusted to not exceed a maximum operating voltage (VDD max) that ensures lifetime of the digital circuit unit.

18. A method of driving a display panel in a display panel driving device configured to control driving of the display panel, the method comprising:
transmitting and receiving, by a power management integrated circuit (PMIC), load mode information of a digital circuit unit; and
adjusting, by the PMIC, an external power supply voltage according to a load mode of the digital circuit unit to supply the adjusted external power supply voltage to the digital circuit unit.

19. The method of claim 18, wherein, when a load current of the digital circuit unit increases, the external power supply voltage is adjusted to be greater than or equal to a minimum operating voltage (VDD min) that ensures operation of the digital circuit unit.

20. The method of claim 18, wherein, when a load current of the digital circuit unit decreases, the external power supply voltage is adjusted to not exceed a maximum operating voltage (VDD max) that ensures lifetime of the digital circuit unit.
